(19) United States
(12) Patent Application Publication
(10) Pub. No.: US 2013/0212959 A1
(43) Pub. Date: Aug. 22, 2013

(54) ASPHALT SHINGLE SOLAR POWER DEVICE, SYSTEM AND INSTALLATION METHOD

(71) Applicant: James John Lopez, Gilroy, CA (US)

(72) Inventor: James John Lopez, Gilroy, CA (US)

(21) Appl. No.: 13/591,387

(22) Filed: Aug. 22, 2012

Related U.S. Application Data
(60) Provisional application No. 61/526,257, filed on Aug. 22, 2011.

(51) Int. Cl. H01L 31/042

(52) U.S. Cl. CPC H01L 31/0422
USPC 52/173.3

(57) ABSTRACT

The invention is an asphalt shingle based solar power device, system, and installation method for providing asphalt shingles with embedded photovoltaic solar panels that can be installed on a roof in a manner quite similar to that of standard asphalt shingles, with a minimal need for either extra wiring or skilled labor. The invention provides shingles, underlayment layers (roofing paper), and electrical connecting tape which have embedded electrically conductive ribbon cable, such as flat braded electrical wire, configured so that the same nails that assemble the units together also electrically connect the various devices to form a useful photovoltaic electrical grid. Use of other materials and methods, such as specially designed nails with a middle conductive region, optional self-sealing materials to provide water resistance, use of safety disconnect circuits, and the like is also described.

### CROSS REFERENCE TO RELATED APPLICATIONS

This application claims the priority benefit of U.S. provisional application 61/526,257 “ASPHALT SHINGLE SOLAR POWER DEVICE, SYSTEM AND INSTALLATION METHOD”, inventor James John Lopez, filed Aug. 22, 2011; the contents of which are incorporated herein by reference.

### BACKGROUND OF THE INVENTION

1. Field of the Invention

This invention is in the field of solar power and photovoltaic solar cell installation technology

2. Description of the Related Art

As photovoltaic solar cells become cheaper in cost, and fossil fuels become ever more expensive, methods of facilitating large scale use of photovoltaic solar cells (solar cells, solar panels) become increasingly important.

Rooftops provide large areas naturally exposed to the sun, and thus provide a natural location to locate solar cells. However prior art methods of mounting solar cells can be both material and labor intensive. Typically solar panels are mounted on their own support frame, which is bolted onto the roof as a separate structure, after the roof has already been installed. The various photovoltaic cells of the solar panel are connected with complex, difficult to install, and expensive wiring. Thus lower cost methods of providing roof mounted photovoltaic cells are of commercial interest.

Asphalt shingles are one of the most popular types of roof materials. These shingles typically are formed by coating materials such as fiberglass or a paper-felt like material with asphalt, often with a top coating of asphalt and various rock or ceramic granules.

Asphalt shingles are typically installed by a simple process. Typically an underlayment layer or layers of material, such as tar paper, roofing felt, butyl rubber sheet, and the like (here referred to as roofing paper) is applied to the underlying plywood or other material. Then the shingles are installed, typically by hammering only a few nails, such as four nails, through the shingle and underlayment layer(s) and into the material below.

### BRIEF SUMMARY OF THE INVENTION

The invention is based, in part, on the insight that it would be desirable to provide asphalt shingles that not only have embedded photovoltaic solar panels, but which additionally can be installed in a manner quite similar to that of standard asphalt shingles, with a minimal need for either extra wiring or skilled labor.

In one embodiment, the invention is a modified asphalt shingle with both embedded photovoltaic solar panels and embedded ribbon wiring intended to be both physically installed into a roof, and electrically connected to an underlying rooftop electrical grid, using the same set of nails, which in some embodiments may be only four nails per shingle.

In another embodiment, the invention is also a system for providing an underlying electrical grid capable of supporting the above modified asphalt shingles. This system (in addition to the photovoltaic asphalt shingles described above will) often also consist of a modified underlayment layer (roofing paper), itself with its own system of embedded ribbon wiring, specially designed rolls of tape with embedded ribbon wiring, and optionally specially designed nails with a middle conductive region, but a non-conductive head and tip region, along with optional self-sealing materials, safety disconnect circuits, and the like.

In another embodiment, the invention is also a method of attaching photovoltaic solar panels to a roof surface using nails that function to both hold the photovoltaic solar panels in place and also serve to establish electrical connections.

### BRIEF DESCRIPTION OF THE DRAWINGS

FIG. 1 shows a photovoltaic asphalt shingle according to the invention.

FIG. 2 shows how the shingle of FIG. 1 may be constructed as a composite of multiple layers.

FIG. 3 shows a roll of electrical roofing felt or paper according to the invention.

FIG. 4 shows how the invention's photovoltaic asphalt shingles may be both mounted on a roof and electrically connected to the photovoltaic power grid using the same nails or other type of connectors.

FIG. 5 shows an example of a partially insulated metal (e.g. copper) nail intended to be used to mount the photovoltaic asphalt shingles to both the roof and the photovoltaic power grid.

### DETAILED DESCRIPTION OF THE INVENTION

In one embodiment, the invention may comprise an asphalt shingle or composition roof tile modified for solar photovoltaic arrays. In a preferred embodiment, the photovoltaic arrays are mounted in an asphalt shingle with three tabs.

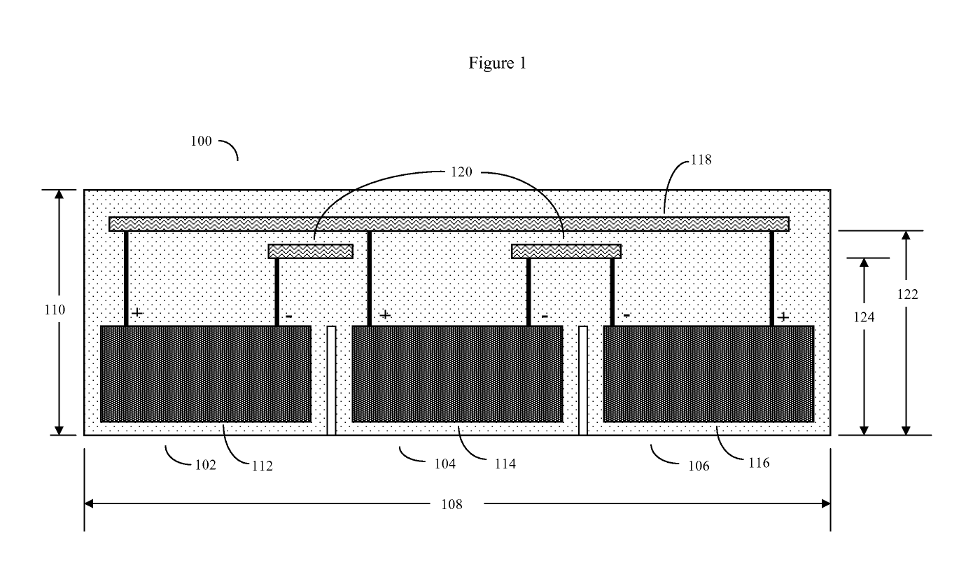

FIG. 1 shows an example of this shingle (100). In this example, the shingle may be composed of three tabs (102), (104), (106). The shingles may have a length (108) that is often between about 32 inches long and 39 inches long. The shingles may have a width (110) that is often between about 12 inches long and 14 inches long. A photovoltaic panel or panels (e.g. a solar panel) will generally be mounted in the lower portion of the shingle, roughly in the same region as the separate portions of each tab (112), (114), and (116). These solar panels will have internal electrical connections to various sections of flat braded conductive wire (often copper wire) (118), (120), or conductive ribbon (often a copper ribbon) that is flat, and is able to maintain its electrical connection when a nail is passed through it, and often will be between about ½ inches to 1 inch wide. Suitable examples of this conductive material include Omni 246B large flat tinned bare copper, French braded ribbon ⅞″ wide.

Often the conductive wire(s) (118), (120) will be arranged so that all the positive polarity solar panel connections are disposed a first parallel distance, such as 12 inches away from the base of the tabs (122) (assuming a 13″ or wider shingle), while all of the negative polarity solar panel connections are disposed a second parallel distance, such as 10 inches away from the base of the tabs (124).

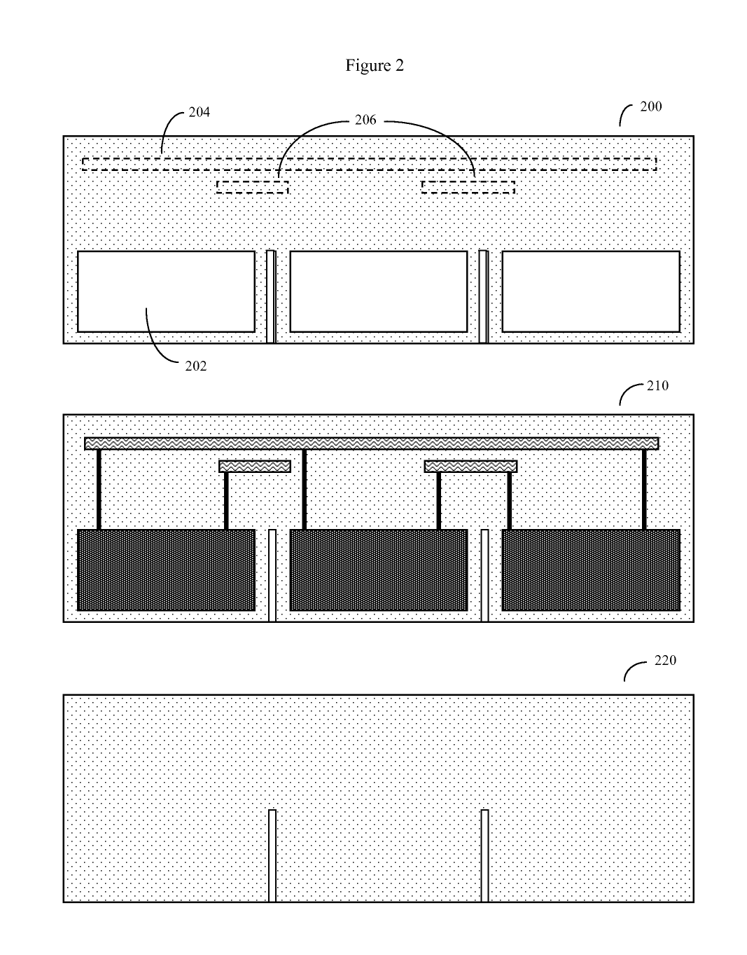

This shingle (100) may often be constructed by laminating several (e.g. three) different layers together. These different layers are shown in FIG. 2. The top layer (200) can consist of a standard asphalt shingle material, modified with holes or windows (202) (for improved water protection, a water tight transparent window may also be used here) to allow light to penetrate to next middle layer (210). Often the top layer will also have various printed guides (204), (206) to instruct the roofers where to nail the holes

The middle layer (210) will have the solar panels and associated wiring, often mounted on a suitable material, which may be asphalt shingle material or other material, so that the material may be laminated to the top and bottom layers and form a secure, water tight, shingle.

The bottom layer (220) can be composed of a simple layer of material, such as asphalt shingle material, or other material, again selected to be water resistant and durable. Layers (200), (210), and (220) can then be laminated together, forming shingle (100).

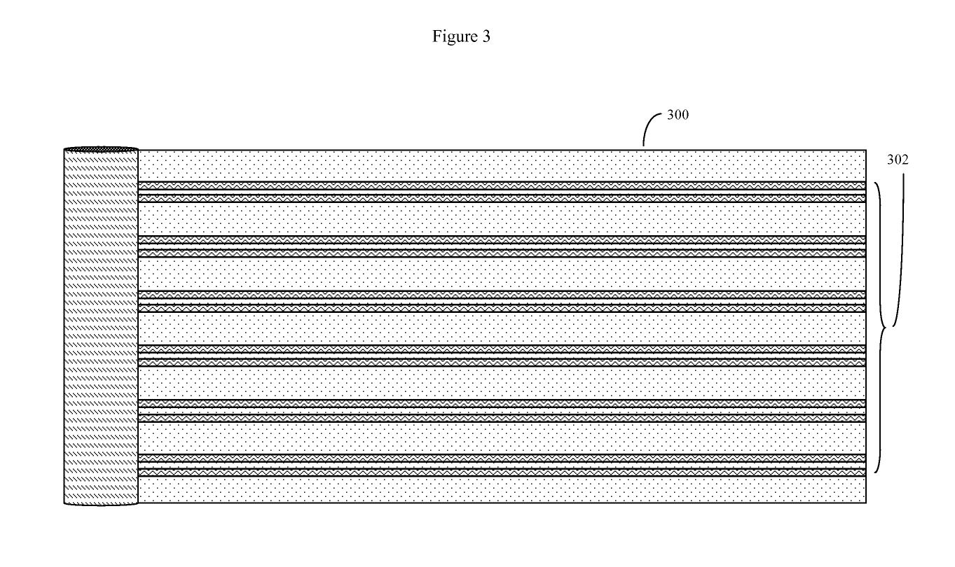

The invention also makes use of a new type of electrically conductive roofing paper. This roofing paper will often be available in rolls, with dimensions such as 38 inches×100 feet, and the like. This is shown in a partially unrolled form in FIG. 3 (300).

The roofing paper will have a series of parallel conductive ribbons in it as well (302), disposed so that the spacing between the various parallel conductive ribbons exactly matches the spacing between the conductive ribbons (118), (120) in the counterpart asphalt shingles (100), so that the singles, when properly positioned and nailed into place, will create electrical connections in which each parallel conductive ribbon in the roofing paper (302) is always connected to the conductive ribbons (118), (120) in the overlaying photovoltaic shingles (100) that have with the same polarity (e.g. all positive “+” or all negative “−”).

The roofing paper (300) will often have printed lines with guides on it to help the roofer properly position the roofing shingles (not shown), and inside the paper would have a copper braded ribbon or other conductive material. Again this material may a French braded ribbon ⅞″ wide, called large flat tinned copper, serial number Omni 246B large flat tinned bare copper, or other material.

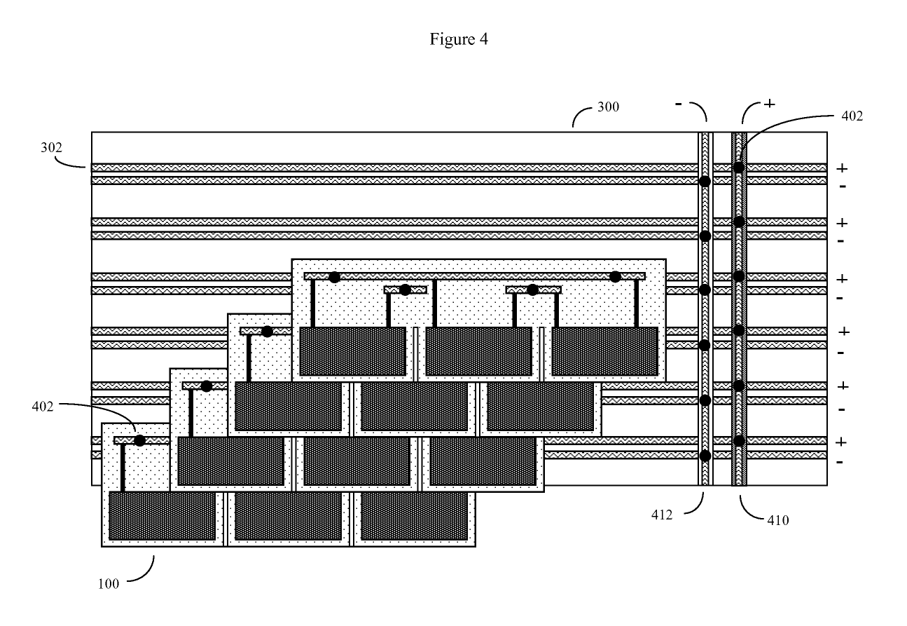

FIG. 4 shows how the various photovoltaic shingles (100) can be nailed into position on a roof (for example into plywood or into an optional underlying air permeable sheet such as corrugated plastic, that is configured to allow at least some outside air may flow through the air permeable sheet, thereby removing excess heat from the underside of the shingles.

In FIG. 4, assume that the surface is the plywood surface of a new roof (not shown). First the installer will unroll the conductive roofing paper (300) and place it (e.g. nail or glue it) securely over the support material and into the proper position. Next the installer, using printed guides on the surface of the roofing paper, will carefully position the various photovoltaic tiles (100).

Using the printed guides provided on both the conductive roofing paper (300) and the surface of the photovoltaic shingle (204), (206), to facilitate proper alignment, the installer will then carefully nail the photovoltaic shingles (100) into position so that the nails (402), (500) will go through both the shingle's conductive ribbon or braded copper wire (118)/(120) and through the conductive ribbon or braded copper wire (302) on the underlying conductive roofing paper (300), and through to the underlying support (e.g. plywood, corrugated plastic, etc.) on the top of the roof. Using this scheme, as few as four nails would suffice to both securely fasten the shingle to the roof and establish an electrical connection to the photovoltaic power grid. These nails are shown (from the top head side) as the small dark circles (402) in FIG. 4.

Note that when the shingles are properly applied, each individual parallel conductive ribbon or braded wire (302) in the underlying roofing paper will end up having the same polarity. In order to combine the power from multiple rows of shingles, according to the invention, the different parallel rows (302) of the same polarity on the underlying roofing paper may be connected to each other by use of conductive ribbons, such as a positive and negative conductive ribbon (410), (412). These conductive ribbons will usually be nailed into place before the shingles (100) are nailed into place. The conductive ribbons may be conveniently color coded and also may have markings as well in order to facilitate proper connections.

Any of the shingle (100), roofing paper (300), and conductive ribbon (410), (412) may incorporate additional materials to help form a better water seal. For example, the flat electrical cables in any of these may be covered by a sheathe, such as a plastic sheathe, and on the inside of the sheathe the conductive ribbon or braded wire may be surrounded by a layer of plastic, such as butyl rubber, silicon grease, asphalt, or other material designed to flow into gaps caused by the nail hole, and seal these gaps without disrupting the electrical connection, thereby preventing leaks and accidental short circuits.

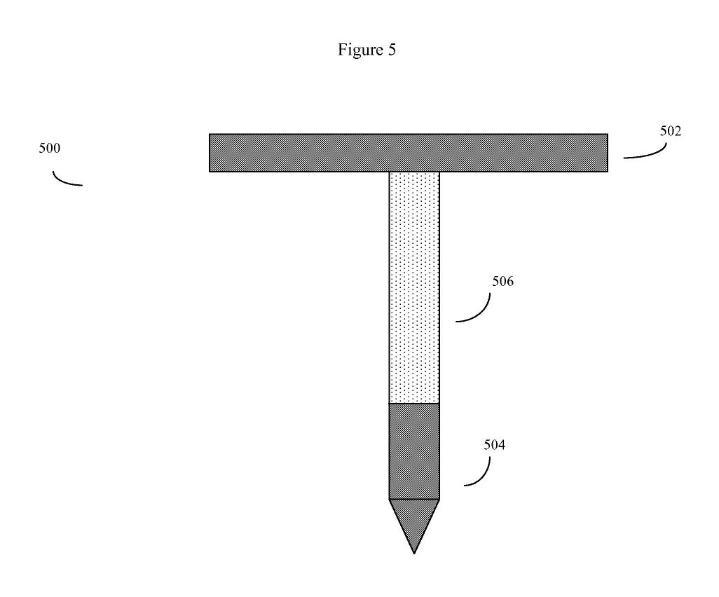

As previously discussed, various types of nails or other connectors may be used to both assemble the system and create a good electrical connection. One type of nail is shown in FIG. 5.

In this example, the underlying body of the nail (500) can be made of a material, such as a metal alloy, chosen to be both conductive, still function adequately as a nail, yet maintain a good electrical connection over time. The head (502) and tip (504) of the nail, however, can be treated, e.g. by powder coating with a non-conductive material or other process, to be non- conductive. Thus the central portion of the nail shaft (506) will remain conductive.

Either alternatively or additionally, after the nails have been nailed into position, the top of the nail can be sealed or protected against the elements by applying an additional layer of tape or sealing compound (not shown).

Electrical Safety Considerations:

In an alternate embodiment, the shingles could optionally have various electrical protection mechanisms, such as a fuse or circuit breaker, for safety reasons to disconnect the shingle from the electrical grid when needed.

At the end of the tape, where it gets soldered, an electrical safety circuit can also be used to disconnect. Other shut-offs can be put in as required by various electrical safety standards.

Use of Alternative Materials:

The shingle need not be made from asphalt, and may in alternative embodiments contain other materials, such as ground up or recycled tires, etc. Such embodiments can increase the ecological appeal of the shingles by also promoting recycling

Rubber can also be molded around the various electrical panels. The shingle may thus have the appearance of an asphalt shingle visually, but may incorporate other materials.

1. A photovoltaic asphalt shingle configured to be both mounted on a roof and electrically connected to an underlying photovoltaic power grid using the same connectors.

2. The shingle of claim 1, wherein said connectors are metal nails.

3. The shingle of claim 2, wherein said metal nails are insulated on the head and at the tip, but in which at least some of the nail shaft between said head and tip is electrically conductive

4. The shingle of claim 1, wherein at least some of the underlying photovoltaic power grid comprises a plurality of parallel braded conductive wires or a conductive metal strip embedded in roofing felt or paper.

5. The shingle of claim 4, wherein at least some of said braded conductive wires or metal strips are connected in a substantially perpendicular direction by one or more conductive ribbons, said conductive ribbons affixed and electrically connected to said braded conductive wires or metal strip by conductive metal nails.

6. The shingle of claim 5, wherein said conductive ribbon comprises braded conductive wires or a conductive metal strip embedded in a nonconductive support material.

7. The shingle of claim 6, wherein said conductive ribbon additionally comprises a self-sealing material capable of flowing around nail holes and forming a watertight seal.

8. The shingle of claim 4, wherein said roofing felt or paper further comprises a self-sealing material capable of flowing around nail holes and forming a watertight seal.

9. The shingle of claim 4, wherein said roofing felt or paper is mounted on top of an air permeable sheet, wherein at least some outside air may flow thorough said air permeable sheet, thereby removing excess heat from the underside of said shingles.

10. The shingle of claim 4, wherein shingle is mounted on top of an air permeable sheet, wherein at least some outside air may flow thorough said air permeable sheet, thereby removing excess heat from the underside of said shingles, and in which said roofing felt or paper is mounted underneath said sheet.

11. The shingle of claim 1, wherein said shingle comprises one or more electrical safety circuits configured to electrically disconnect said shingle from said underlying power grid in the event of an electrical malfunction.

12. The shingle of claim 1, wherein said shingle additionally comprises a self-sealing material capable of flowing around nail holes and forming a watertight seal.
